(19) United States
(12) Patent Application Publication
(10) Pub. No.: US 2009/0260231 A1
(43) Pub. Date: Oct. 22, 2009

(54) DEVICE TO CHECK AND CORRECT THE POSITION OF PLATES FOR ELECTRONICS AND RELATED METHOD

(75) Inventor: Andrea BACCINI, San Biagio di Callalta (TV) (IT)

Correspondence Address: HAMRE, SCHUMANN, MUELLER & LARSON, P.C., P.O. BOX 2902, MINNEAPOLIS, MN, 55402-0902, US

(73) Assignee: APPLIED MATERIALS BACCINI SPA CON SOCIO UNICO, San Biagio di Callalta (TV) (IT)

(21) Appl. No.: 12/256,791

(22) Filed: Oct. 23, 2008

(30) Foreign Application Priority Data
Oct. 24, 2007 (IT) UD2007A000199

(51) Int. Cl. H05K 3/10

(52) U.S. Cl. 29/846; 29/760

(57) ABSTRACT

A device to check and correct the position of plates for electronics, associated with a loading station of the plates and with a printing unit of an apparatus for depositing metal or other material, in which there is a video acquisition member to acquire at least an image indicating a position occupied by the plate in the loading station. The device comprises movement and positioning means suitable for the reciprocal alignment of the printing unit and the plate, as detected in the loading station, there also being present a control, processing and governing unit.

### FIELD OF THE INVENTION

The present invention concerns a device to check and correct the position of plates for electronics and relative method.

The present invention is applied preferably, but not exclusively, for the deposition of metal or other material, conductive or not, for example by means of silk-screen printing, on plates, of the green-tape or silicon wafer type or other suitable material, for the production of electronic circuits.

### BACKGROUND OF THE INVENTION

A device is known, for checking and correcting the position of plates for the deposition of metal or other conductive material with the purpose of generating on said plates metal tracks, for example conductive, or other circuits according to a desired circuit topology. The known check and correction device is associated with a plate-loading support suitable to load plates coining from an adjacent apparatus or from a feed line, such as for example a conveyor belt.

The loading support is associated with a print unit suitable to deposit metal or other material on the plate. The check and correction device comprises a centering board, mobile, on which the loading support is fixed so as to allow the alignment of the plate deposited on the loading support with the print unit. The check device also comprises a TV camera suitable to detect the exact positioning of the plate on the loading support in order to move the centering board so as to allow the desired alignment before performing the deposition.

One disadvantage of the known device is that the plates, for example made of silicon or other similar material, are rather fragile and the movements produced by the centering board can accidentally cause micro-fractures or produce other unwanted defects, therefore diminishing the productivity of the deposition of metal or other materials. It is possible to reduce the speed of movement of the centering board, but this increases the time needed to perform the above-mentioned deposition.

One purpose of the present invention is to achieve a device to check and correct the position of plates for electronics that allows to render the positioning of a plate rapid and effective, so as to perform the deposition of the metal or other materials correctly and according to the desired circuit topology.

A further purpose of the present invention is to achieve a method to check and correct the position of plates for electronics.

The Applicant has devised, tested and embodied the present invention to overcome the shortcomings of the state of the art and to obtain these and other purposes and advantages.

### SUMMARY OF THE INVENTION

The present invention is set forth and characterized in the independent claims, while the dependent claims describe other characteristics of the invention or variants to the main inventive idea.

In accordance with the above purposes, a device to check and correct the position of plates for electronics can be employed in an apparatus for the deposition of metal or other material on plates, for example silicon wafers or other suitable material. The device is associated with a loading station of the apparatus suitable for the loading of plates coming from an adjacent feed line and with a print unit suitable for the deposition of the metal or other material.

The device comprises a video acquisition member for the acquisition of at least an image indicating a position occupied by a plate deposited in the loading station of said apparatus.

According to a characteristic feature of the present invention the device comprises movement and positioning means, suitable to allow a reciprocal alignment between the print unit and the plate as detected on the loading station. A control, processing and governing unit is connected to the video acquisition member and is suitable to drive the movement members. In this way the deposition of the metal or other material by the print unit is performed coherently with the position of the plate disposed on the loading station.

According to a variant of the invention, the movement and positioning means is associated with the print unit and suitable to move it. In this way it is the print unit that is aligned with respect to the plate disposed in the loading station.

According to a variant of the invention, the movement and positioning means is associated with the plate so as to allow the alignment of the plate with respect to the print unit.

According to a further variant of the present invention the movement and positioning means is associated with the loading station so as to move the loading station with respect to the print unit. In this way the plate disposed on the loading station is moved with it until the desired alignment between plate and print unit is achieved.

According to a variant of the present invention the video acquisition member is also suitable to check for defects in a plate before the metal or other materials is deposited on the plate.

The present invention also concerns a method to check and correct the position of plates for electronics for the deposition on the plates of metal or other material. The method according to the present invention comprises a first step in which a plate is disposed in a position on a loading station.

The method also comprises a second step in which a video acquisition member detects the position of the plate on the loading station and sends the information to a control and governing unit that registers and calculates the exact lying position of the plate in said loading station.

The method also comprises a third step in which metal or other material is deposited on the plate by means of a print unit.

According to a characteristic feature of the present invention, in said third step, before performing the deposition of the metal or other material, the print unit and the plate are positioned in the correct print position.

According to a variant of the method according to the present invention, in the third step the print unit is moved so as to align it with the position occupied by the plate in the loading station.

According to a further variant, during the third step the plate is moved so as to be aligned with the position of the print unit.

According to a further variant of the method according to the present invention, in the third step the loading station, on which the plate is deposited, is moved so that the plate is positioned in the desired position with respect to the print unit.

### BRIEF DESCRIPTION OF THE DRAWINGS

These and other characteristics of the present invention will become apparent from the following description of a preferential form of embodiment, given as a non-restrictive example with reference to the attached drawings wherein:

FIG. 1 is a schematic view of a device according to the present invention;

FIG. 2 is a schematic view of the device in FIG. 1 in a first operating configuration;

FIG. 3 is a schematic view of the device in FIG. 1 in a second operating configuration.

### DETAILED DESCRIPTION OF A PREFERENTIAL FORM OF EMBODIMENT

With reference to the attached drawings, a device to check and correct the position of plates for electronics according to the present invention is applicable to an apparatus 10 for the deposition of metal or other material on plates, also called hereafter wafers 12, for example made of silicon or other suitable material. The apparatus 10 is fed by a belt 16 suitable for transferring the wafers 12 from a preceding apparatus for the treatment of wafers 12. The device is associated with a loading station 14 suitable to receive the wafers 12 from the feeding belt 16. The device is also associated with a print unit 18 for the deposition, for example by means of silk-screen printing, on the wafers 12 of metal or other material suitable for the generation of conductor tracks according to a predefined and desired circuit topology. The device comprises a TV camera 24 suitable for the acquisition of images relating to a specific surface area of the loading station 14 and suitable to be occupied by a wafer 12 being worked before the printing.

The TV camera 24 is of a known type and has a video acquisition resolution coherent with precision required for detecting the position of the wafer 12 in the loading station 14. The TV camera 24 is connected in a known manner to a control unit 22 in order to process the images acquired, allowing to calculate the lying coordinates of a specific and predetermined reference point of the wafer 12 deposited on the loading station 14.

According to a characteristic feature of the invention, the device also comprises movement and positioning means 30, of the known type, stably coupled to the print unit 18 and suitable to move the print unit 18 on a plane horizontal and parallel to a plane identified by a supporting surface of the loading station 14 of wafers 12. The movement and positioning means 30 is driven by means of linear and rotary actuators, of a known type and not shown in the drawings, driven by means of commands given by the control unit 22. The movement and positioning means 30 moves the print unit 18 in two directions, for example reciprocally orthogonal. Moreover, the movement and positioning means 30 allows the print unit to rotate around to a predetermined axis of rotation, orthogonal to the above-mentioned directions.

The device described heretofore functions as follows.

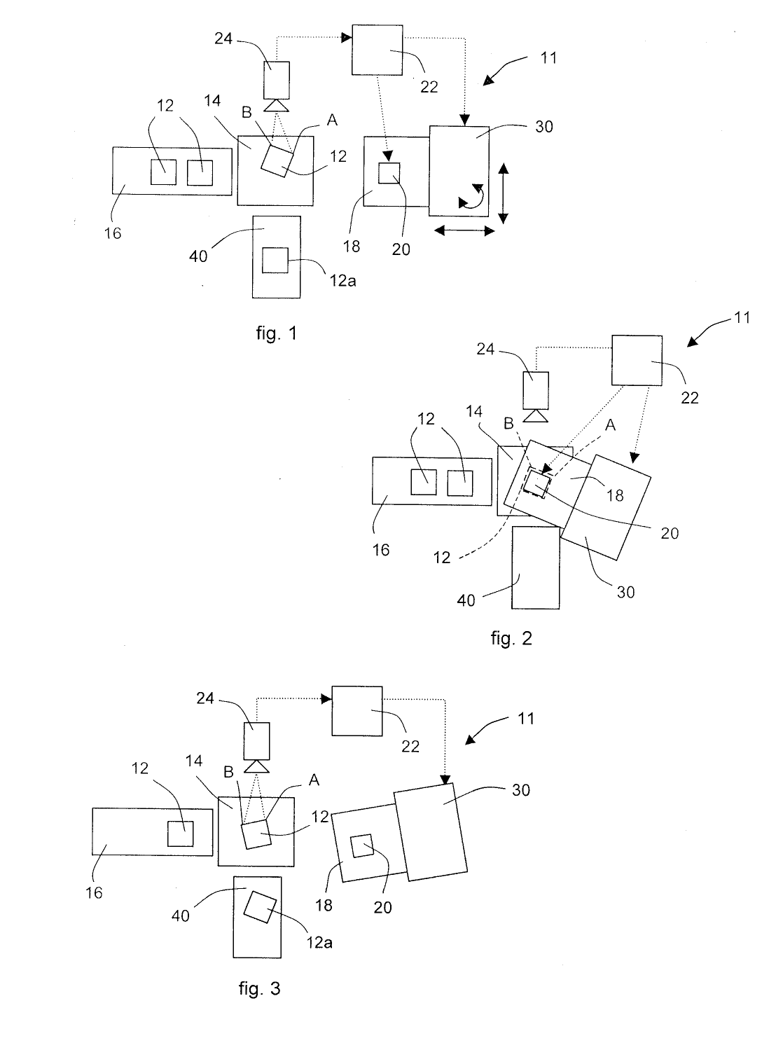

When a wafer 12 is deposited on the loading station 14 (FIG. 1), the TV camera 24 acquires at least an image of the position occupied by the wafer 12 on the surface area of the loading station 14. The TV camera 24 communicates the image, in a known manner, to the control and data processing unit 22 which calculates with the desired precision the coordinates of at least two specific points A, B of the wafer 12 deposited on the loading station 14. In this way it is possible to establish the exact position occupied by the wafer 12 in the surface area of the loading station 14, both with reference to the position occupied by the wafer 12 and also with reference to a possible position rotated with respect to a reference position, for example horizontal.

The control unit 22 (FIG. 2) activates the movement and positioning means 30 so as to position the print unit 18 above the wafer 12 and align it with specific reference points of the print head 20 with the reference points A, B previously acquired by means of the TV camera 24.

The control unit 22 commands the activation of the print head 20 of the print unit 18 for the deposition of the metal on the wafer 12 according to the desired circuit topology. At the end of the deposition the movement and positioning means 30 moves the print unit 18, distancing it. The wafer 12a on which the metal has been deposited is discharged from the loading station 14 for example on an exit belt 40.

It is clear that modifications and/or additions of parts may be made to the position check and correction device as described heretofore, without departing from the field and scope of the present invention. For example, it comes within the field and scope of the present invention to provide that the print unit 18 is fixed and that the movement and positioning means 30 moves the print head 20 so as to align it with the wafer 12. It also comes within the field and scope of the present invention to provide that the TV camera 24 also allows to acquire an image to check the conformity of the wafer 12 before depositing the metal, allowing to prevent deposition in the case where the wafer 12 is defective.

It is also clear that, although the present invention has been described with reference to some specific examples, a person of skill in the art shall certainly be able to achieve many other equivalent forms of device to check and correct the position of an electronic circuit and relative method, having the characteristics as set forth in the claims and hence all coming within the field of protection defined thereby.

1. A device to check and correct the position of plates for electronics, associated with a loading station of said plates and a printing unit of an apparatus for depositing metal or other material, in which there is a video acquisition member to acquire at least an image indicating a position occupied by the plate in the loading station, the device comprising movement and positioning means able to allow a reciprocal alignment of the printing unit and the plate, according to the position detected in the loading station, there also being present a control, processing and governing unit.

2. A device as in claim 1, wherein said movement and positioning means is associated with the printing unit in order to move the printing unit and to align said printing unit with respect to said plate.

3. A device as in claim 1, wherein said movement and positioning means is associated with said plate in order to move said plate and to align said plate with said printing unit.

4. A device as in claim 1, wherein said movement and positioning means is associated with said loading station in order to align said loading station with respect to said printing unit, so that said plate is disposed in the desired position with respect to said printing unit.

5. A device as in claim 2, wherein said movement and positioning means is able to move the printing unit in two reciprocally orthogonal directions.

6. A device as in claim 5, wherein said movement and positioning means is able to move the printing unit around an axis of rotation orthogonal to said orthogonal directions.

7. A device as in claim 1, wherein said video acquisition member is suitable to check for defects in a plate before the metal or other materials are deposited.

8. A method to check and correct the position of plates for electronics, comprising:
a first step in which a plate is deposited in a loading station; and
a second step in which a video acquisition member detects the position of the plate and sends the information to a control and governing unit which registers and calculates the exact position of the plate lying in said loading station; and
a third step in which metal or other material is deposited on the plate by means of a printing unit, wherein in said third step, before depositing the metal or other material, the printing unit and the plate are put in the correct printing position.

9. A method as in claim 8, wherein in said third step the printing unit is moved so as to align said printing unit with the position occupied by said plate in the loading station.

10. A method as in claim 8, wherein in said third step said plate is moved so as to be aligned with the position of the printing unit.

11. A method as in claim 8, wherein in said third step the loading station, on which said plate is deposited, is moved so that said plate is positioned in the desired position with respect to the printing unit.
